(19) United States
(12) Patent Application Publication
(10) Pub. No.: US 2009/0008701 A1
(43) Pub. Date: Jan. 8, 2009

(54) NONVOLATILE MEMORY DEVICE AND METHOD OF FABRICATING THE SAME

(75) Inventors: Dong-Hyun KIM, Gyeonggi-do (KR); Gyung-Jin MIN, Seoul (KR); Chang-Jin KANG, Gyeonggi-do (KR); Seung-Pil CHUNG, Seoul (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggid-do (KR)

(21) Appl. No.: 11/555,126

(22) Filed: Oct. 31, 2006

(30) Foreign Application Priority Data
Oct. 12, 2006 (KR) 10-2006-0099519

(51) Int. Cl. H01L 29/00; H01L 21/3205

(52) U.S. Cl. 257/324; 438/593; 257/E29.001; 257/E21.294

(57) ABSTRACT

A nonvolatile memory device includes a semiconductor substrate, a charge trap layer formed on the semiconductor substrate, a blocking layer formed on the charge trap layer, and a gate electrode formed on the blocking layer. Sides of blocking layer extend laterally beyond sides of the charge trap layer and lateral sides of the gate electrode.

### CROSS-REFERENCE TO RELATED APPLICATION

This application claims benefit of priority to Korean Patent Application No. 10-2006-0099519, filed on Oct. 12, 2006, the disclosure of which is incorporated herein by reference in its entirety.

### BACKGROUND

1. Field of Invention

Embodiments exemplarily described herein relate to a method of fabricating a nonvolatile memory device, and more particularly, to a nonvolatile memory device and a method of fabricating the same which can improve the efficiency of electron injection and the reliability of data deletion and can prevent deterioration of a breakdown voltage.

2. Description of the Related Art

Memory devices are classified into volatile memory devices and nonvolatile memory devices. Volatile memory devices, such as dynamic random access memory (DRAM) devices and static random access memory (SRAM) devices, can be programmed/erased at high speed and are highly likely to lose data over time. Nonvolatile memory devices, such as read only memory (ROM) devices, are programmed/erased at relatively low speed and can store data permanently. Recently, nonvolatile memory devices that can be electronically programmed/erased, such as electronically erasable programmable read only memory (EEPROM) devices or flash memory devices, have been developed.

In general, EEPROM devices or flash memory devices have a structure comprising a first insulation layer, a charge trap layer, a second insulation layer, and a control gate electrode that are sequentially formed on a semiconductor substrate. Electrons present in the semiconductor substrate can be injected into the charge trap layer when a coupling voltage is applied to the charge trap layer by the control gate electrode and thus there is an electrical potential difference between the charge trap layer and the semiconductor substrate.

The voltage coupling effect on a charge trap layer is dependent on the capacitance between a control gate electrode and the charge trap layer. In order to enable electron injection at low voltages, the voltage coupling effect must be increased. In order to increase the voltage coupling effect, the capacitance between a control gate electrode and a charge trap layer must be increased. It has been suggested that the capacitance between a control gate electrode and a charge trap layer can be increased by forming a second insulation layer of metal oxide having a high dielectric constant between the charge trap layer and the control gate electrode. However, a metal oxide layer having a high dielectric constant produces conductive polymer on its sides when being etched. Undesirably, the conductive polymer acts as a path along which electrons can move between a control gate electrode and a charge trap layer, thereby deteriorating a breakdown voltage of the device.

### SUMMARY

Embodiments exemplarily described herein provide a nonvolatile memory device that can improve the efficiency of electron injection and the reliability of data deletion while preventing deterioration of a breakdown voltage.

Embodiments exemplarily described herein also provide a method of fabricating a nonvolatile memory device which can improve the efficiency of electron injection and the reliability of data deletion and can prevent deterioration of a breakdown voltage.

However, the embodiments are not restricted to those set forth above. These and other advantages will become more apparent to one of daily skill in the art by referencing the detailed description given below.

According to one embodiment exemplarily described herein, a nonvolatile memory device may include a semiconductor substrate, a charge trap layer on the semiconductor substrate, a blocking layer on the charge trap layer, and a gate electrode on the blocking layer. A side of the blocking layer may extend laterally beyond a side of the charge trap layer and a side of the gate electrode.

According to another embodiment exemplarily described herein, a width of the blocking layer may be greater than a width of the charge trap layer and a width of the gate electrode.

According to another embodiment exemplarily described herein, a nonvolatile memory device may include a semiconductor substrate and a gate stack formed on the semiconductor substrate. The gate stack may include a charge trap layer and a gate electrode above the charge trap layer. Further, the gate stack may include a protrusion between the charge trap layer and the gate electrode such that the protrusion extends beyond a sidewall of the gate stack to prevent deterioration of a breakdown voltage of the nonvolatile memory device.

According to another embodiment exemplarily described herein, a method of fabricating a nonvolatile memory device includes forming a charge trap layer on a semiconductor substrate, forming a blocking layer on the charge trap layer, and forming a gate electrode on the blocking layer. In the method, a side of the blocking layer extends laterally beyond a side of the charge trap layer and a side of the gate electrode.

### BRIEF DESCRIPTION OF THE DRAWINGS

The above and other features and advantages will become more apparent by describing in detail preferred embodiments thereof with reference to the attached drawings, in which:

FIG. 1 is a cross-sectional view of a nonvolatile memory device according to one embodiment;

FIG. 2 is a cross-sectional view of a nonvolatile memory device according to another embodiment;

FIG. 3 is a cross-sectional view of a nonvolatile memory device according to another embodiment;

FIG. 4 is a cross-sectional view of a nonvolatile memory device according to another embodiment;

FIG. 5 is a cross-sectional view of a nonvolatile memory device according to another embodiment;

FIG. 6 is a cross-sectional view of a nonvolatile memory device according to another embodiment; and

FIGS. 7 through 13 are cross-sectional views for exemplarily explaining a method of fabricating a nonvolatile memory device according to one embodiment.

### DETAILED DESCRIPTION

Exemplary embodiments will now be described more fully with reference to the accompanying drawings. The invention may, however, be embodied in many different forms and should not be construed as being limited to the embodiments set forth herein; rather, these embodiments are provided so that this disclosure will be thorough and complete, and will fully convey the concept of the invention to those skilled in the art.

Therefore, in this disclosure, detailed descriptions of processes, structures, and techniques that are well known to one of ordinary skill in the art will not be presented in order to avoid any misunderstanding.

The terms used in this disclosure are exemplary and thus do not limit the scope of the embodiments described herein. The elements described in this disclosure in plural form may also be construed as singular, unless specifically stated otherwise. It will be understood that, as used herein, the term “comprising” or “comprises” is open-ended, and includes one or more stated elements, steps and/or functions without precluding one or more unstated elements, steps and/or functions. Also, it will be understood that, as used herein, the term “and/or” includes any combination of one or more stated items. Like reference numerals in the drawings denote like elements, and thus their description will be omitted.

In this disclosure, the term “inner side” refers to portions that are close to the central axis of each cell of a nonvolatile memory device, and the term “outer side” refers to portions that are distant from the central axis of each cell of a nonvolatile memory device.

A nonvolatile memory device according to one embodiment will hereinafter be described in detail with reference to the accompanying drawings.

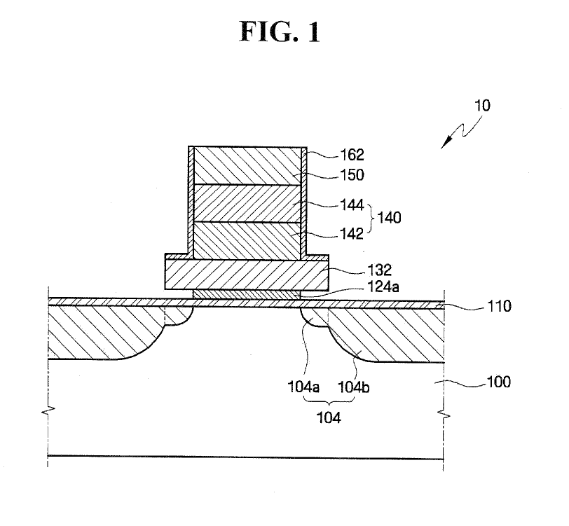

FIG. 1 is a cross-sectional view of a nonvolatile memory device 10 according to one embodiment. Referring to FIG. 1, the nonvolatile memory device 10 can be characterized as a gate stack including a charge trap layer 124a and a gate electrode 140 which are formed on a semiconductor substrate 100.

The semiconductor substrate 100 may include a material such as Si, Ge, SiGe, GaP, GaAs, SiC, SiGeC, InAs, InP, or the like. The semiconductor substrate 100 may be a p- or n-type substrate. The semiconductor substrate 100 may include a p-type well (not shown) which is doped with p-type impurities or an n-type well (not shown) which is doped with n-type impurities.

Source/drain regions 104 are formed in the semiconductor substrate 100 and are separated from each other. The source/drain regions 104 are doped with p- or n-type impurities. A channel region is formed between a pair of adjacent source/drain regions 104. Each of the source/drain regions 104 may include a heavily doped region 104b and a lightly doped region 104a. The lightly doped region 104a may be located between the heavily doped region 104b and the channel region.

A tunnel layer 110, the charge trap layer 124a, and a blocking layer 132 are sequentially deposited on the semiconductor substrate 100.

The tunnel layer 110 is interposed between the semiconductor substrate 100 and the charge trap layer 124a and provides a path along which electrons can move. The tunnel layer 110 covers not only the channel region but also the source/drain regions 104. Accordingly, lateral sides of the tunnel layer 110 extend beyond lateral sides of the blocking layer 132. Stated another way, the sides of the tunnel layer 110 extend laterally beyond sides of the blocking layer 132. The tunnel layer 110 may include silicon oxide, silicon oxynitride, or the like. The tunnel layer 110 may be formed to a thickness of about 30-50 Å, but the embodiments disclosed herein are not restricted thereto.

The charge trap layer 124a retains electrons that are injected thereinto from the semiconductor substrate 100 through the tunnel layer 110. For this, the charge trap layer 124a may include a material having excellent electron retention properties. For example, the charge trap layer 124a may include a material such as silicon nitride or silicon oxynitride or a high dielectric material (hereinafter referred to as a high-k material) such as aluminum oxide (AlOₓ) or hafnium oxide (HfOₓ), or combinations thereof. The charge trap layer 124a may be formed to a thickness of about 30-100 Å, but the embodiments disclosed herein are not restricted thereto.

The charge trap layer 124a overlaps the channel region of the semiconductor substrate 100. In other words, the lateral sides of the charge trap layer 124a are substantially aligned with the boundaries between the channel region and the source/drain regions 104. Also, the lateral sides of the charge trap layer 124a are substantially aligned with the lateral sides of a gate electrode 140, which will be described later in detail.

The blocking layer 132 prevents electrons injected into the charge trap layer 124 from infiltrating into the gate electrode 140. Accordingly, the blocking layer 132 may include a material having poor electron retention properties. For example, the blocking layer 132 may include a material such as silicon oxide or a metal oxide having a high dielectric constant. Examples of the metal used to form the metal oxide include aluminum (Al), hafnium (Hf), cobalt (Co), and combinations thereof. For example, the blocking layer 132 may include hafnium aluminum oxide (HfAlOₓ), cobalt aluminum oxide (CoAlOₓ), or combinations thereof.

The blocking layer 132 may be formed to a sufficient thickness to properly perform its electron-blocking function. The blocking layer 132 may be thicker than the tunnel layer 110 or the charge trap layer 124a. For example, the blocking layer 132 may be formed to a thickness of 50-150 Å, but the embodiments disclosed herein are not restricted thereto.

Lateral sides of the blocking layer 132 extend beyond lateral sides of the charge trap layer 124a. In other words, lateral sides of the charge trap layer 124a are recessed with respect to lateral sides of the blocking layer 132.

Lateral portions of the blocking layer 132 overlap the channel region. Also, the lateral portions of the blocking layer 132 partially overlap the source/drain regions 104 which are adjacent to the channel region. For example, each of the lateral sides of the blocking layer 132 may be substantially aligned with the boundary between the lightly doped region 104a and the heavily doped region 104b of a corresponding source/drain region 104.

The gate electrode 140 is formed on the blocking layer 132. The gate electrode 140 may be comprised of a stack of at least one of a polysilicon layer doped with n- or p-type impurities, a metallic layer, a metal silicide layer, and a metal nitride layer. Examples of the metal used to form the metallic layer, the metal silicide layer, or the metal nitride layer include tungsten (W), cobalt (Co), nickel (Ni), titanium (Ti), tantalum (Ta), or the like. Referring to FIG. 1, the gate electrode 140 includes a first gate electrode layer 142 and a second gate electrode layer 144. The first gate electrode layer 142 may include tantalum nitride (TaN) and the second gate electrode layer 144 may include tungsten (W), but the embodiments disclosed herein are not restricted thereto.

The gate electrode 140 is recessed with respect to the lateral sides of the blocking layer 132 the blocking layer 132. In other words, lateral sides of the blocking layer 132 extend beyond the lateral sides of the gate electrode 140. The gate electrode 140 overlaps the channel region. The gate electrode 140 may be used as a doping mask during the formation of the lightly doped regions 104a. Thus, the lateral sides of the gate electrode 140 may be substantially aligned with the boundaries between the channel region and the source/drain regions 104. Also, the lateral sides of the gate electrode 140 may be substantially aligned with the lateral sides of the charge trap layer 124a.

According to the embodiment shown in FIG. 1, electrons are injected from the semiconductor substrate 100 into the charge trap layer 124a through the tunneling layer 110 by Fowler-Nordheim tunneling due to a high voltage applied to the gate electrode 140. In other words, the amount of electric charge injected into the charge trap layer 124a is determined according to an electric field that is generated between the gate electrode 140 and the semiconductor substrate 100. The electric field generated by the gate electrode 140 is perpendicular to the bottom of the gate electrode 140. As described above, the lateral sides of the gate electrode 140 may be substantially aligned with the lateral sides of the charge trap layer 124a so that the width of the gate electrode 140 is substantially the same as the width of the charge trap layer 124a. In this case, the entire surface of the charge trap layer 124a is affected by the electric field generated by the gate electrode 140. Thus, electrons in the electric field generated by the gate electrode 140 can be effectively injected into the charge trap layer 124a.

If the blocking layer 132 includes metal oxide having a high dielectric constant, a conductive polymer (not shown) may be formed on the sidewalls of the blocking layer 132 during the patterning of the blocking layer 132. Since the gate electrode 140 is recessed with respect to the lateral sides of the blocking layer 132, the lateral sides of the blocking layer 132 extend beyond the direct influence of the electric field generated by the gate electrode 140. Also, the lateral sides of the charge trap layer 124a are recessed with respect to the lateral sides of the blocking layer 132 (i.e., lateral sides of the blocking layer 132 extend beyond lateral sides of the charge trap layer 124a), and are relatively distant from the conductive polymer. Because the lateral sides of the blocking layer 132 extend beyond lateral sides of the charge trap layer 124a and the gate electrode 140, the sidewall profile of the gate stack exemplarily shown in FIG. 1 can be characterized as having a straight with a protrusion extending beyond the sidewall. Due to the presence of the blocking layer 132 configured as described above (i.e., due to the presence of the protrusion extending beyond the sidewall of the gate stack), it is possible to reduce the probability that electrons injected into the charge trap layer 124a will infiltrate into the gate electrode 140 through the conductive polymer and thus to prevent deterioration of a breakdown voltage regardless of the existence of the conductive polymer.

A first insulation layer pattern 150 is formed on the gate electrode 140. The first insulation layer pattern 150 may include a material such as silicon nitride. The lateral sides of the first insulation layer pattern 150 are substantially aligned with the lateral sides of the gate electrode 140. The first insulation layer pattern 150 is optional.

A second insulation layer 162 covers part of the top surface of the blocking layer 132 that is not covered by the gate electrode 140 and also covers the lateral sides of the gate electrode 140 and the first insulation layer pattern 150. The second insulation layer 162 may also cover the top surface of the first insulation layer pattern 150. The second insulation layer 162 may serve as an etch stop layer and may be comprised of an oxide material such as a middle temperature oxide (MTO) layer or a low temperature oxide (LTO).

The second insulation layer 162 may be thinner than the underlying structure, and may be conformal to the underlying structure.

A spacer (not shown) may be provided on the semiconductor layer 162.

Nonvolatile memory devices according to other embodiments will be described in greater detail below. In these other embodiments, like reference numerals represent like elements and, thus, descriptions thereof will be skipped or simplified.

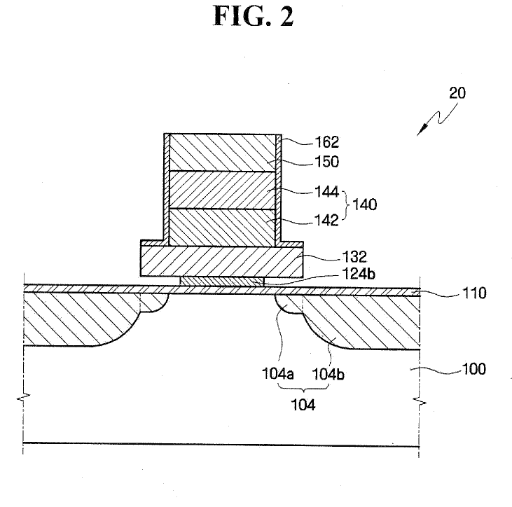

FIG. 2 is a cross-sectional view of a nonvolatile memory device 20 according to another embodiment. Referring to FIG. 2, the nonvolatile memory device 20 is different from the nonvolatile memory device 10 illustrated in FIG. 1 in that a charge trap layer 124b is recessed with respect to the lateral sides of a gate electrode 140 and is thus not substantially aligned with the gate electrode 140. That is, lateral sides of the gate electrode 140 extend beyond lateral sides of the charge trap layer 124b.

As shown in FIG. 2, the width of the charge trap layer 124b is smaller than the width of the gate electrode 140. Thus, the area of the charge trap layer 124b that can be affected by an electric field generated by the gate electrode 140 is smaller than the area of the charge trap layer 124a that can be affected by an electric field generated by the gate electrode 140. As a result, the efficiency of electron injection is highly likely to be lower in the nonvolatile memory device 20 than in the nonvolatile memory device 10. However, since a blocking layer 132 protrudes with respect to the lateral sides of the gate electrode 140 (i.e., since lateral sides of the blocking layer 132 extend beyond lateral sides of the gate electrode 140) and the charge trap layer 124b is recessed further from the lateral sides of the blocking layer 132 than the charge trap layer 124a, it is possible to further prevent deterioration of a breakdown voltage even when conductive polymer is formed on the sidewalls of the blocking layer 132.

The nonvolatile memory device 20 has a relatively wide design rule, and thus, no problem regarding electron injection efficiency arises. The nonvolatile memory device 20 is highly convenient for the situation when there is a strong need to prevent deterioration of a breakdown voltage.

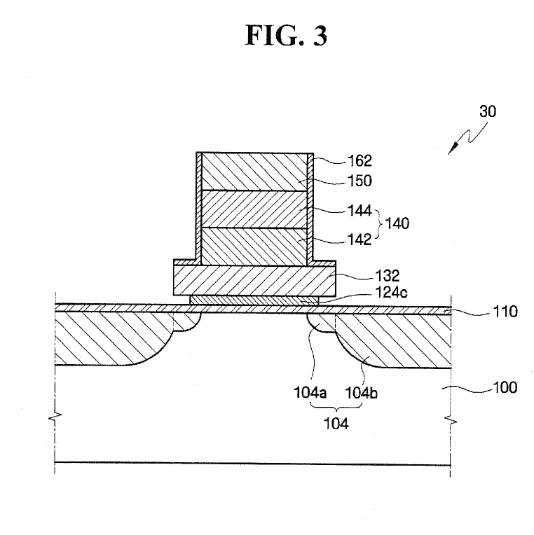

FIG. 3 is a cross-sectional view of a nonvolatile memory device 30 according to another embodiment. Referring to FIG. 3, the nonvolatile memory device 30 is different from the nonvolatile memory device 10 illustrated in FIG. 1 in that a charge trap layer 124c extends beyond the lateral sides of a gate electrode 140 and is thus not substantially aligned with the gate electrode 140. However, the charge trap layer 124c, like the charge trap layer 124a illustrated in FIG. 1, is recessed with respect to the lateral sides of a blocking layer 132.

As shown in FIG. 3, the charge trap layer 124c extends beyond the range of an electric field generated by the gate electrode 140, thus ensuring efficient injection of electrons by the electric field. Electrons that are injected into the charge trap layer 124c may move beyond the range of the electric field generated by the gate electrode 140. Since it is difficult for the gate electrode 140 to control portions of the charge trap layer 124c that are outside the range of the electric field generated by the gate electrode 140, a data erase operation may not be able to be properly performed in the corresponding portions of the charge trap layer 124c. However, the charge trap layer 124c is recessed with respect to the lateral sides of the blocking layer 132 (i.e., lateral sides of the blocking layer 132 extend beyond lateral sides of the charge trap layer 124c), thereby preventing the area of portions of the charge trap layer 124c that are not controlled by the gate electrode 140 from being excessively increased. Therefore, it is possible to prevent cell operating properties of the nonvolatile memory device 30 from excessively deteriorating.

As described above, since the charge trap layer 124c is recessed with respect to the lateral sides of the blocking layer 132, it is possible to prevent deterioration of a breakdown voltage regardless of whether conductive polymer is formed on the sidewalls of the blocking layer 132.

In view of the above, the nonvolatile memory device 30 may be highly suitable for application to devices that require high electron injection efficiency.

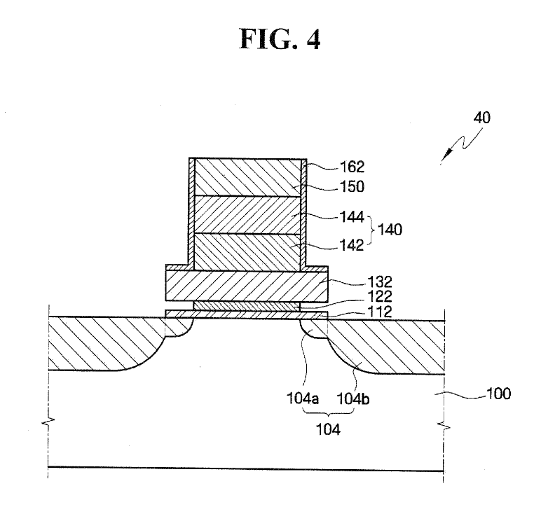

FIG. 4 is a cross-sectional view of a nonvolatile memory device 40 according to another embodiment. Referring to FIG. 4, the nonvolatile memory device 40 is different from the nonvolatile memory device 10 illustrated in FIG. 1 in that a tunnel layer 112 covers the channel region and partially covers source/drain regions 104 of a semiconductor substrate 100. In other words, the lateral sides of the tunnel layer 112 are substantially aligned with the lateral sides of a blocking layer 132. Accordingly, each of the lateral sides of the tunnel layer 112 can be substantially aligned with the boundary between a lightly doped region 104a and a heavily doped region 104b of a corresponding source/drain region 104.

As shown in FIG. 4, a charge trap layer 122, similar to the charge trap layer 124a shown in FIG. 1, is substantially aligned with a gate electrode 140, thereby offering high electron injection efficiency. Also, the charge trap layer 122 is recessed with respect to the lateral sides of the blocking layer 132, thereby preventing deterioration of a breakdown voltage regardless of whether conductive polymer is formed on the sidewalls of the blocking layer 132.

While FIG. 4 illustrates a nonvolatile memory device 40 including a charge trap layer 122 having a similar configuration as the charge trap layer 124a of the nonvolatile memory device 10 illustrated in FIG. 1, the charge trap layer 122 may alternatively have the configuration of the charge trap layer 124b illustrated in FIG. 2 or the charge trap layer 124c illustrated in FIG. 3.

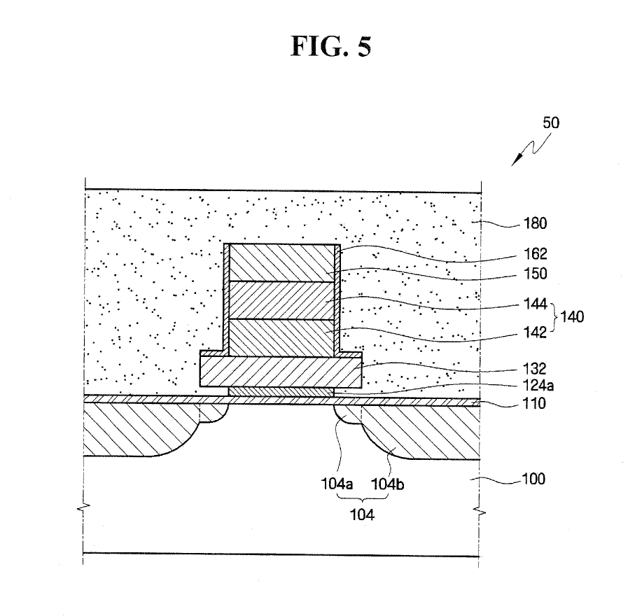

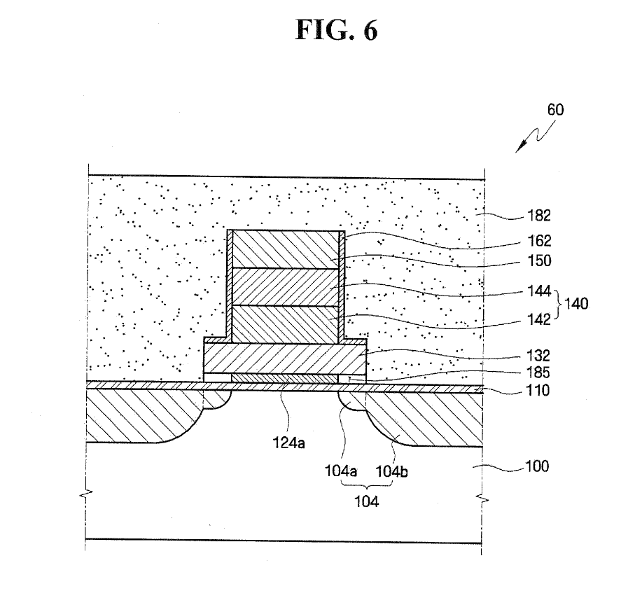

Each of the nonvolatile memory devices 10, 20, 30, and 40 that are respectively illustrated in FIGS. 1 through 4 may also include an interlayer dielectric layer which covers a gate electrode formed on a semiconductor substrate, and this will hereinafter be described in detail with reference to FIGS. 5 and 6. FIG. 5 is a cross-sectional view of a nonvolatile memory device 50 according to another embodiment and FIG. 6 is a cross-sectional view of a nonvolatile memory device 60 according to another embodiment.

Referring to FIGS. 5 and 6, the nonvolatile memory devices 50 and 60 include almost the same structure as the nonvolatile memory device 10 illustrated in FIG. 1 except that the nonvolatile memory devices 50 and 60 also include interlayer dielectric layers 180 and 182, respectively. The interlayer dielectric layers 180 and 182 may include a silicon oxide layer, a silicon oxynitride layer, a silicon nitride layer, or a stacked combination thereof.

FIG. 5 illustrates an interlayer dielectric layer 180 that is formed to completely fill recesses between the blocking layer 132 and the tunnel layer 110 in the structure illustrated in FIG. 1. FIG. 6 illustrates an interlayer dielectric layer 182 that is formed on the structure illustrated in FIG. 1 but leaves voids 185 by not filling the recesses between the blocking layer 132 and the tunnel layer 110 in the structure illustrated in FIG. 1. It will be appreciated, however, that the recesses in the structure illustrated in FIG. 1 may be partially or completely filled with a thermal oxide layer or a native oxide layer. In addition, the nonvolatile memory device 20, 30, and 40 respectively illustrated in FIGS. 2, 3, and 4 may also include the interlayer dielectric layer 180 or 182. Moreover, contact holes, plugs, interconnections, and interlayer insulation layers may also be formed in or on the interlayer dielectric layer 180 or 182.

A method of fabricating a nonvolatile memory device according to an exemplary embodiment will hereinafter be described in detail focusing on the fabrication of the nonvolatile memory device 10 illustrated in FIG. 1 and differences between the fabrication of the nonvolatile memory device 10 and the fabrication of the nonvolatile memory devices 20, 30 and 40 respectively illustrated in FIGS. 2, 3, and 4.

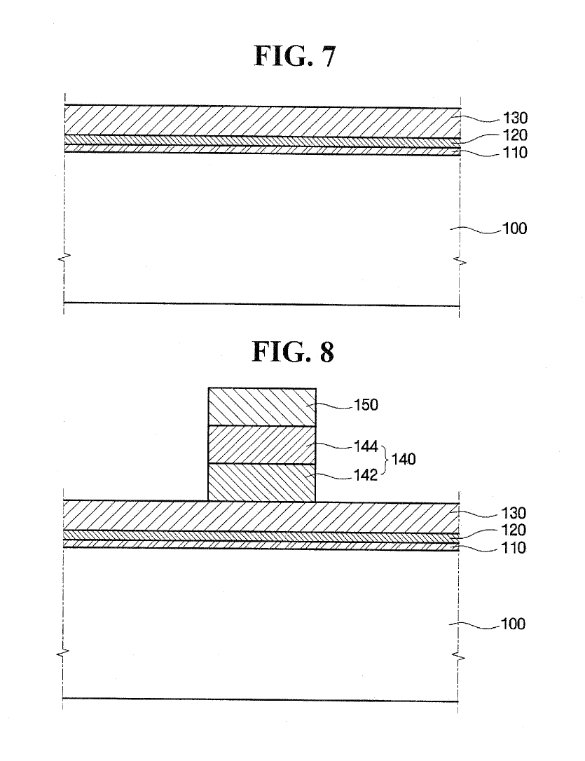

FIGS. 7 through 13 are cross-sectional views for explaining a method of fabricating a nonvolatile memory device according to one exemplary embodiment.

Referring to FIG. 7, a tunnel layer 110, a first lamination layer 120 that is needed to form a charge trap layer, and a second lamination layer 130 that is needed to form a blocking layer are sequentially formed on a semiconductor substrate 100.

The tunnel layer 110 may be formed, for example, using a chemical vapor deposition (CVD) method, a low pressure chemical vapor deposition (LPCVD) method, or a plasma enhanced chemical vapor deposition (PECVD) method. The tunnel layer 110 may include silicon oxide. In this case, the tunnel layer 110 may be formed using a thermal oxidation method.

The first lamination layer 120 and the second lamination layer 130 may be formed using the same method as the tunnel layer 110. If the first lamination layer 120 and the second lamination layer 130 include metal oxide, then the first lamination layer 120 and the second lamination layer 130 may be formed using an LPCVD method, an atomic layer deposition (ALD) method, a physical vapor deposition (PVD) method, or a metal organic CVD method. Alternatively, the first lamination layer 120 and the second lamination layer 130 may be formed by forming a metallic layer using an LPCVD method, an atomic layer deposition (ALD) method, a physical vapor deposition (PVD) method, or a metal organic CVD method and oxidizing the metallic layer.

Referring to FIG. 8, a first gate conductive layer, a second gate conductive layer and a first insulation layer are formed on the second lamination layer 130. Then, the first gate conductive layer, the second gate conductive layer, and the first insulation layer are patterned using a photolithography method, thereby forming a gate electrode 140 that includes a first gate electrode 142, a second gate electrode 144, and a first insulation layer pattern 150.

The first gate conductive layer and the second gate conductive layer may be formed, for example, using a CVD, LPCVD, ALD, PVD, or MOCVD method. The first insulation layer may be formed, for example, using a CVD, LPCVD, or PECVD method.

The photolithography method used in the formation of the gate electrode 140 may be performed as follows. A photoresist layer is formed on the first insulation layer. Then, the photoresist layer is exposed and developed, thereby forming a photoresist pattern. Thereafter, the first insulation layer, the second gate conductive layer, and the first gate conductive layer are sequentially etched using the photoresist pattern as an etching mask. The etching of the first insulation layer, the second gate conductive layer, and the first gate conductive layer may be conducted using, for example, a dry etching method. A first insulation layer pattern 150 obtained by etching the first insulation layer may serve as a hard mask during the etching of the second gate conductive layer and the first gate conductive layer.

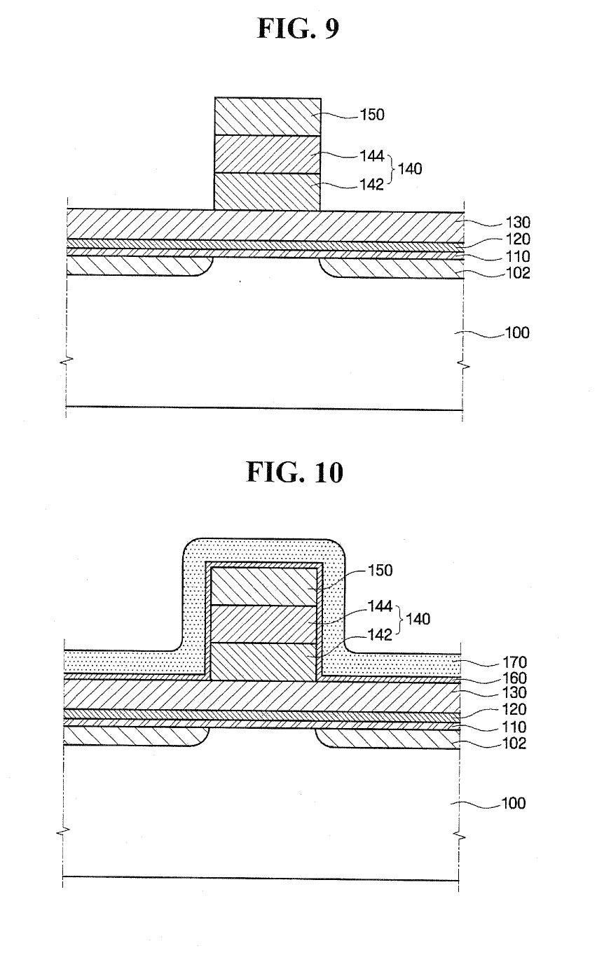

Referring to FIG. 9, n- or p-type impurities are implanted to a low concentration into the semiconductor substrate 100 using the first insulation layer pattern 150 and the gate electrode 140 as doping masks, thereby forming lightly doped regions 102 at both sides of the gate electrode 140 and forming a channel region between the lightly doped regions 102.

Referring to FIG. 10, a second insulation layer 160 and a third insulation layer 170 are sequentially formed on the structure illustrated in FIG. 9. The second and third insulation layers 160 and 170 may be subsequently used to form spacers.

The second insulation layer 160 may be formed using a deposition method such as CVD, LPCVD, or PECVD. The formation of the second insulation layer 160 may be conducted under a low temperature condition or a middle temperature condition.

The third insulation layer 170 may include a material such as silicon nitride or silicon oxynitride and be formed according to a process such as CVD, LPCVD, or PECVD.

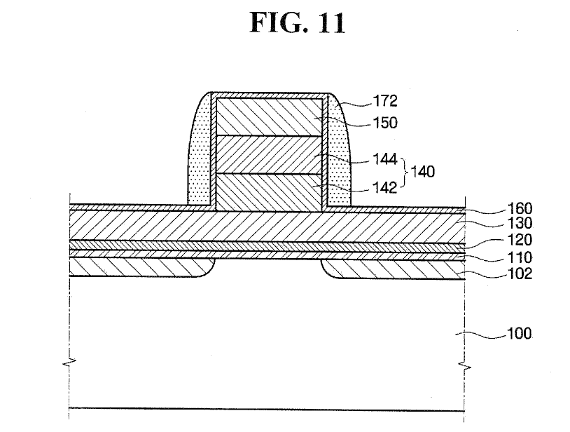

Referring to FIG. 11, the third insulation layer 170 is etched back to form a pair of spacers 172 on both sides of the first insulation layer pattern 150. The second insulation layer 160 may serve as an etch stopper and still cover the underlying structure.

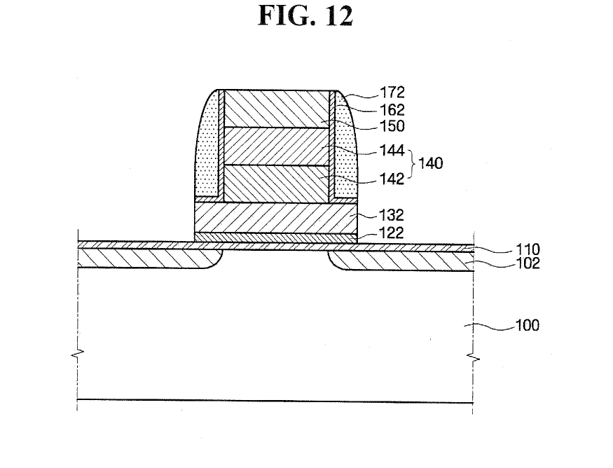

Referring to FIG. 12, the second insulation layer 160, the second lamination layer 130, and the first lamination layer 120 that are not covered by the spacers 172 are etched away, thereby forming a second insulation layer pattern 162, a blocking layer 132, and a charge trap layer 122 that are each substantially aligned with the outer sidewalls of the spacers 172. If the etching of the second insulation layer 160, the second lamination layer 130, and the first lamination layer 120 is performed without using any mask, part of the second insulation layer 160 that covers the first insulation layer pattern 150 may also be etched away to expose the first insulation layer pattern 150. If the etching of the second insulation layer 160, the second lamination layer 130, and the first lamination layer 120 is performed using an etching gas having a high etching selectivity of the second insulation layer 160, the second lamination layer 130, and the first lamination layer 120 with respect to the spacers 172 and the first insulation layer pattern 150, then the spacers 172 and the first insulation layer pattern 150 may remain unetched.

As described above, if the blocking layer 132 includes metal oxide, conductive polymer may be formed on the sidewalls of the blocking layer 132 as a result of the etching of the second insulation layer 160, the second lamination layer 130, and the first lamination layer 120.

In order to fabricate the nonvolatile memory device 40 illustrated in FIG. 4, part of the tunnel layer 110 that is not covered by the spacers 172 may also be etched.

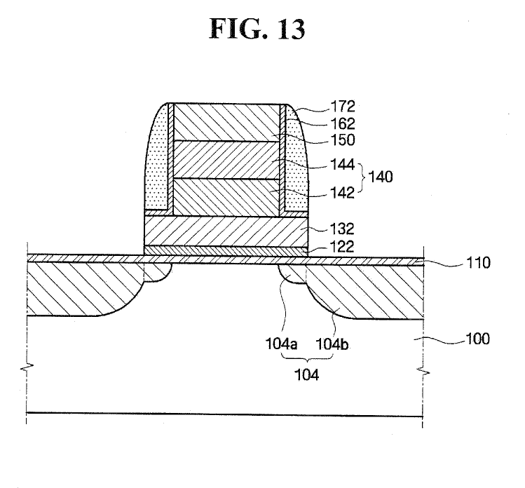

Referring to FIG. 13, n- or p-type impurities are implanted to a high concentration into the semiconductor substrate 100 using the spacers 172 and the gate electrode 140 as doping masks, thereby forming source/drain regions 104, each source/drain region 104 comprising a heavily doped region 104b and a lightly doped region 104a and the boundary between the heavily doped region 104b and the lightly doped region 104a being substantially aligned with the outer sidewall of a corresponding spacer 172.

Thereafter, the charge trap layer 122 is selectively removed and is thus recessed with respect to the lateral sides of the blocking layer 132, thereby completing the fabrication of the nonvolatile memory device 10 illustrated in FIG. 1. In one embodiment, selective removal of the charge trap layer 122 can be terminated when the charge trap layer 122 exhibits the configuration of the charge trap layer 124a shown in FIG. 1 (i.e., when lateral sides of the charge trap layer are substantially aligned with lateral sides of the gate electrode 140).

In one embodiment, selective removal of the charge trap layer 122 may be performed through isotropic etching. The isotropic etching may be conducted using a dry etching method or a wet etching method.

For example, the isotropic etching may be performed using a chemical dry etching method that involves the use of an etching gas containing at least one of NF₃, CF₄, SF₆, CHF₃, and CH₂F₂. Alternatively, the isotropic etching may be performed using a wet etching method that involves the use of an etchant containing phosphoric acid. In one embodiment, the etching selectivity between the charge trap layer 122 and the blocking layer 132 may be set to at least about 10:1. In another embodiment, the etching selectivity between the charge trap layer 122 and the blocking layer 132 may be set to about 100:1, thereby preventing the blocking layer 132 from being undesirably etched with the charge trap layer 122.

As a result of isotropic etching under the aforementioned etching conditions, the spacers 172 and the first insulation layer pattern 150 are at least partially removed. According to the embodiment illustrated in FIG. 1, the spacers 172 are completely removed, and the first insulation layer pattern 150 remains substantially unetched, but the embodiments disclosed herein are not restricted thereto.

In another embodiment, selective removal of the charge trap layer 122 can be terminated before lateral sides of the charge trap layer 122 have been aligned with lateral sides of the gate electrode 140 such that the charge trap layer 122 exhibits the configuration of the charge trap layer 124c illustrated in FIG. 3. In yet another embodiment, selective removal of the charge trap layer 122 can be terminated after lateral sides of the charge trap layer 122 have been aligned with lateral sides of the gate electrode 140 such that the charge trap layer 122 exhibits the configuration of the charge trap layer 124b illustrated in FIG. 2.

In order to fabricate the nonvolatile memory device 50 or 60 illustrated in FIG. 5 or 6, the interlayer dielectric layer 180 or 182 may be formed on the structure illustrated in FIG. 1 (or FIG. 2 or 3) using, for example, a CVD, LPCVD, or PECVD method. The difference between the nonvolatile memory device 50 and the nonvolatile memory device 60 lies in whether the recesses in the structure illustrated in FIG. 1 (or FIG. 2 or 3) is completely filled with an interlayer dielectric layer.

According to embodiments exemplarily described herein, since lateral sides of a charge trap layer are substantially aligned with lateral sides of a gate electrode, it is possible to improve the efficiency of electron injection and the reliability of data erase. In addition, since the charge trap layer and the gate electrode are recessed with respect to a blocking layer, it is possible to prevent deterioration of a breakdown voltage caused by conductive polymer that is formed on the blocking layer.

While the embodiments provided above have been exemplarily shown and described with reference to the drawings above, it will be understood by those of ordinary skill in the art that various changes in form and details may be made therein without departing from the spirit and scope of embodiments of the present invention as defined by the following claims.

What is claimed is:

1. A nonvolatile memory device comprising:
a semiconductor substrate;
a charge trap layer on the semiconductor substrate;
a blocking layer on the charge trap layer; and
a gate electrode on the blocking layer,
wherein a side of the blocking layer extends laterally beyond a side of the charge trap layer and a side of the gate electrode.

2. The nonvolatile memory device of claim 1, wherein the side of the charge trap layer is substantially aligned with the side of the gate electrode.

3. The nonvolatile memory device of claim 1, wherein the side of the gate electrode extends laterally beyond the side of the charge trap layer.

4. The nonvolatile memory device of claim 1, wherein the side of the charge trap layer extends laterally beyond the side of the gate electrode.

5. The nonvolatile memory device of claim 1, further comprising source/drain regions in the semiconductor substrate and defining a channel region.

6. The nonvolatile memory device of claim 5, wherein the side of the charge trap layer is substantially aligned with a boundary between the channel region and a source/drain region.

7. The nonvolatile memory device of claim 5, wherein the side of the charge trap layer extends laterally beyond a boundary between the channel region and a source/drain region.

8. The nonvolatile memory device of claim 5, wherein a boundary between the channel region and a source/drain region extends laterally beyond the side of the charge trap layer.

9. The nonvolatile memory device of claim 5, wherein:
each source/drain region comprises a lightly doped region and a heavily doped region; and
a side of the blocking layer is substantially aligned with a boundary between the lightly doped region and the heavily doped region.

10. The nonvolatile memory device of claim 1, further comprising a tunnel layer between the semiconductor substrate and the charge trap layer, wherein a side of the tunnel layer extends laterally beyond a side of the blocking layer.

11. The nonvolatile memory device of claim 1, further comprising a tunnel layer between the semiconductor substrate and the charge trap layer, wherein a side of the tunnel layer is substantially aligned with a side of the blocking layer.

12. The nonvolatile memory device of claim 1, further comprising an insulation layer covering a top surface of the blocking layer between the side of the gate electrode and the side of the blocking layer.

13. The nonvolatile memory device of claim 12, wherein the insulation layer covers the side of the gate electrode.

14. The nonvolatile memory device of claim 1, wherein the blocking layer comprises metal oxide.

15. The nonvolatile memory device of claim 14, wherein the metal oxide is hafnium aluminum oxide (HfAlOₓ), cobalt aluminum oxide (CoAlOₓ), or a combination thereof.

16. The nonvolatile memory device of claim 1, further comprising an interlayer dielectric layer on the gate electrode, the blocking layer and the substrate, wherein the interlayer dielectric layer is vertically between the substrate and the blocking layer.

17. The nonvolatile memory device of claim 1, further comprising an interlayer dielectric layer on the gate electrode, the blocking layer and the substrate, wherein a void is defined laterally between the charge trap layer and the interlayer dielectric layer.

18. A nonvolatile memory device comprising:
a semiconductor substrate;
a charge trap layer on the semiconductor substrate;
a blocking layer on the charge trap layer; and
a gate electrode on the blocking layer,
wherein a width of the blocking layer is greater than a width of the charge trap layer and a width of the gate electrode.

19. The nonvolatile memory device of claim 18, wherein the width of the charge trap layer is substantially the same as the width of the gate electrode.

20. The nonvolatile memory device of claim 18, wherein the width of the charge trap layer is less than the width of the gate electrode.

21. The nonvolatile memory device of claim 18, wherein the width of the charge trap layer is greater than the width of the gate electrode.

22. A nonvolatile memory device comprising:
a semiconductor substrate; and
a gate stack formed on the semiconductor substrate, the gate stack including a charge trap layer and a gate electrode above the charge trap layer,
wherein the gate stack includes a protrusion between the charge trap layer and the gate electrode, the protrusion extending beyond a sidewall of the gate stack to prevent deterioration of a breakdown voltage of the nonvolatile memory device.

23. The nonvolatile memory device of claim 22, wherein the gate stack includes a blocking layer between the charge trap layer and the gate electrode, wherein the protrusion comprises a portion of the blocking layer extending beyond the sidewall of the gate stack.

24. The nonvolatile memory device of claim 22, wherein a width of the charge trap layer is substantially the same as a width of the gate electrode.

25. The nonvolatile memory device of claim 22, wherein a width of the charge trap layer is less than a width of the gate electrode.

26. The nonvolatile memory device of claim 22, wherein a width of the charge trap layer is greater than a width of the gate electrode.

27. A method of fabricating a nonvolatile memory device comprising:
forming a charge trap layer on a semiconductor substrate;
forming a blocking layer on the charge trap layer; and
forming a gate electrode on the blocking layer,
wherein a side of the blocking layer extends laterally beyond a side of the charge trap layer and a side of the gate electrode.

28. The method of claim 27, further comprising substantially aligning the side of the charge trap layer with the side of the gate electrode.

29. The method of claim 27, further comprising forming the side of the gate electrode to extend laterally beyond the side of the charge trap layer.

30. The method of claim 27, further comprising forming the side of the charge trap layer to extend laterally beyond the side of the gate electrode.
